(19) United States
(12) Patent Application Publication
(10) Pub. No.: US 2024/0162197 A1
(43) Pub. Date: May 16, 2024

(54) SCALABLE POWER SEMICONDUCTOR DEVICE PACKAGE WITH LOW INDUCTANCE

(71) Applicant: SEMICONDUCTOR COMPONENTS INDUSTRIES, LLC, Scottsdale, AZ (US)

(72) Inventors: Atapol PRAJUCKAMOL, Thanyaburi (TH); Chee Hiong CHEW, Seremban (MY)

(73) Assignee: SEMICONDUCTOR COMPONENTS INDUSTRIES, LLC, Scottsdale, AZ (US)

(21) Appl. No.: 18/508,551

(22) Filed: Nov. 14, 2023

Related U.S. Application Data
(60) Provisional application No. 63/383,932, filed on Nov. 16, 2022.

(51) Int. Cl. H01L 25/07; H01L 23/00; H01L 23/31; H01L 23/498

(52) U.S. Cl. CPC H01L 25/072; H01L 23/3114; H01L 23/49844; H01L 24/40; H01L 24/48; H01L 24/73; H01L 2224/40175; H01L 2224/48137; H01L 2224/48175; H01L 2224/73221; H01L 2924/13091

(57) ABSTRACT

In a general aspect, a power module package includes a substrate that has a ceramic layer with a first primary surface and a second primary surface opposite the first primary surface. The substrate also includes a patterned metal layer disposed on the first primary surface. The package also includes a first plurality of semiconductor die disposed on a first portion of the patterned metal layer. The first plurality of semiconductor die are linearly arranged along a first axis. The package further includes a second plurality of semiconductor die disposed on a second portion of the patterned metal layer. The second plurality of semiconductor die are linearly arranged along a second axis parallel to the first axis.

### RELATED APPLICATIONS

This application claims priority to and the benefit of U.S. Provisional Application No. 63/383,932, filed on Nov. 16, 2022, entitled “MOLDED POWER MODULE PACKAGE,” the disclosure of which is incorporated by reference herein in its entirety.

### TECHNICAL FIELD

This description relates to semiconductor device assemblies. More specifically, this description relates to packaged power semiconductor device circuits.

### BACKGROUND

Semiconductor devices (e.g., semiconductor die) can be included in package assemblies or module packages, where such assemblies can include one or more semiconductor die. For instance, power semiconductor device packages can implement a number of circuits, such as half-bridge circuits that include a plurality of semiconductor die. Some considerations for design and production of such power semiconductor device packages are material costs, and ease of package scaling, such as for different numbers of semiconductor die. Furthermore, a concern regarding performance of such power semiconductor device packages is reduction of parasitic impedances, such as stray inductance.

### SUMMARY

In a general aspect, a power module package includes a substrate that has a ceramic layer with a first primary surface and a second primary surface opposite the first primary surface. The substrate also includes a patterned metal layer disposed on the first primary surface. The power module package also includes a first plurality of semiconductor die disposed on a first portion of the patterned metal layer. The first plurality of semiconductor die are linearly arranged along a first axis. The power-module package further includes a second plurality of semiconductor die disposed on a second portion of the patterned metal layer. The second plurality of semiconductor die are linearly arranged along a second axis parallel to the first axis. The power module package also includes a plurality of power terminals arranged on a first edge of the power module package. The first edge is parallel to the first axis and the second axis. The power module package further includes a switch node terminal arranged on a second edge of the package. The second edge being opposite and parallel to the first edge. The power module package includes a first plurality of signal pins located on a third edge of the package. The third edge is orthogonal to the first edge and the second edge. The power module package further includes a second plurality of signal pins located on a fourth edge of the package. The fourth edge is opposite and parallel to the third edge.

In another general aspect, a power module package includes a substrate including a patterned metal layer disposed thereon, and a first plurality of semiconductor die disposed on a first portion of the patterned metal layer. The first plurality of semiconductor die include a first plurality of power transistors that are linearly arranged along a first axis. The power module package also includes a second plurality of semiconductor die disposed on a second portion of the patterned metal layer. The second plurality of semiconductor die include a second plurality of transistors that are linearly arranged along a second axis parallel to the first axis. The power module package further includes a first plurality of conductive clips respectively coupling the first plurality of power transistors with a third portion of the patterned metal layer disposed between the first portion of the patterned metal layer and the second portion of the patterned metal layer. The third portion of the patterned metal layer is arranged along a third axis that is parallel with the first axis and the second axis. The power module package also includes a second plurality of conductive clips respectively coupling the second plurality of power transistors with a fourth portion of the patterned metal layer disposed between the second portion of the patterned metal layer and the third portion of the patterned metal layer. The fourth portion of the patterned metal layer is arranged along a fourth axis that is parallel with the first axis, the second axis, and the third axis.

In another general aspect, a method for producing a power module package includes coupling a first plurality of semiconductor die with a first portion of a patterned metal layer of a substrate and a second portion of the patterned metal layer, where the first plurality of high-side semiconductor die are linearly arranged on the substrate along a first axis. The method further includes coupling a second plurality of semiconductor die with a third portion of the patterned metal layer and a fourth portion of the patterned metal layer, where the second plurality of semiconductor die are linearly arranged on the substrate along a second axis parallel to the first axis. The method also includes coupling a plurality of power terminals with the substrate, where the plurality of power terminals are arranged on a first edge of the power module package, and the first edge is parallel to the first axis and the second axis. The method also includes coupling a switch node terminal with the substrate, where the switch node terminal is arranged on a second edge of the power module package, and the second edge is opposite and parallel to the first edge. The method further includes coupling a leadframe with the substrate and forming respective wire bonds coupling the leadframe with the plurality of high-side semiconductor switches and the plurality of low-side semiconductor switches. The method also includes coupling a first plurality of signal pins with respective portions of the leadframe, where the first plurality of signal pins are located on a third edge of the power module package that is orthogonal to the first edge and the second edge. The method also includes coupling a second plurality of signal pins with respective portions of the leadframe, where the second plurality of signal pins being located on a fourth edge of the power module package, the fourth edge being opposite and parallel to the third edge.

### BRIEF DESCRIPTION OF THE DRAWINGS

FIG. 1 is a diagram illustrating an example substrate assembly of a semiconductor device module package.

FIG. 2 is a diagram illustrating an example substrate assembly of another semiconductor device module package.

FIG. 3 is a diagram illustrating an example substrate assembly of yet another semiconductor device module package.

FIGS. 4A-4E are diagrams illustrating various views of an example semiconductor device module package.

FIG. 5 is a diagram illustrating another example semiconductor device module package.

FIGS. 6A and 6B are diagrams illustrating current flow in, for example, the semiconductor device module package of FIGS. 4A-4D.

FIG. 7 is a flowchart illustrating an example method for producing a power module package.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

This disclosure relates to packaged semiconductor device apparatus, which can be referred to as packaged modules, semiconductor device module packages, power semiconductor device module packages, and/or packages. Such semiconductor device module packages can include, for example, a half-bridge circuit, a full-bridge circuit, or other circuits. For purposes of illustration, and by way of example, the implementations described herein are directed to half-bridge circuits. Such half-bridge circuits can include a plurality of high-side semiconductor switches (e.g., power transistors) connected in parallel with one another, and a plurality of low-side semiconductor switches (e.g., power transistors) connected in parallel with one another. In some implementations, the approaches illustrated and described herein can be used to implement semiconductor device modules including circuits other than half-bridge circuits.

The approaches described and illustrated herein can reduce material costs, allow for straightforward package scaling, and reduce parasitic impedances, such as stray inductance, as compared to prior approaches. For instance, the example half-bridge circuit package implementations described herein include a plurality of high-side transistors arranged in a single row, and a plurality of low-side transistors arranged in a single row that is parallel to the row of high-side transistors. Further in the example implementations described herein, power supply terminals are arranged on, or located along a first edge of the package, for example, an edge proximate the row of high-side transistors. Also in the example implementations described herein, a switching node terminal is arranged on, or located along a second edge of the package opposite the first edge, for example, an edge proximate the row of low-side transistors. Still further, signal pins of the disclosed example implementations are arranged along a third edge and/or a fourth edge of the package, where the third and fourth edges are orthogonal to the first and second edges.

The example implementations described herein allow for efficient use of substrate space, which can facilitate reduction of material costs as compared to prior implementations of comparable circuits. For instance, such module packages can include a direct-bonded metal (DBM) substrate, such as a direct-bonded copper (DBC) substrate, which can be a primary component of material costs of such packages. Accordingly, reducing substrate size, as compared to previous comparable module packages, is desirable to achieve material cost reductions. By way of example, such substrates can include a ceramic base or ceramic layer on which metal layers, patterned or unpatterned can be formed. In some implementations, a DBM substrate can be configured as a printed circuit board, having circuit traces, conductive vias, etc.

Furthermore, such arrangements also facilitate straightforward scaling of an associated package for different numbers of high-side and low-side switches. For example, the approaches described herein facilitate scaling in a single axis or direction. That is, a substrate, as well as an overall package size, can be increased or decreased along a single axis to respectively accommodate a desired number of low-side and high-side semiconductor switches (e.g., power transistor) die. The example arrangements illustrated and described also allow for implementing a current path (e.g., path length and direction), that can also facilitate low parasitic impedance, such as low stray inductance.

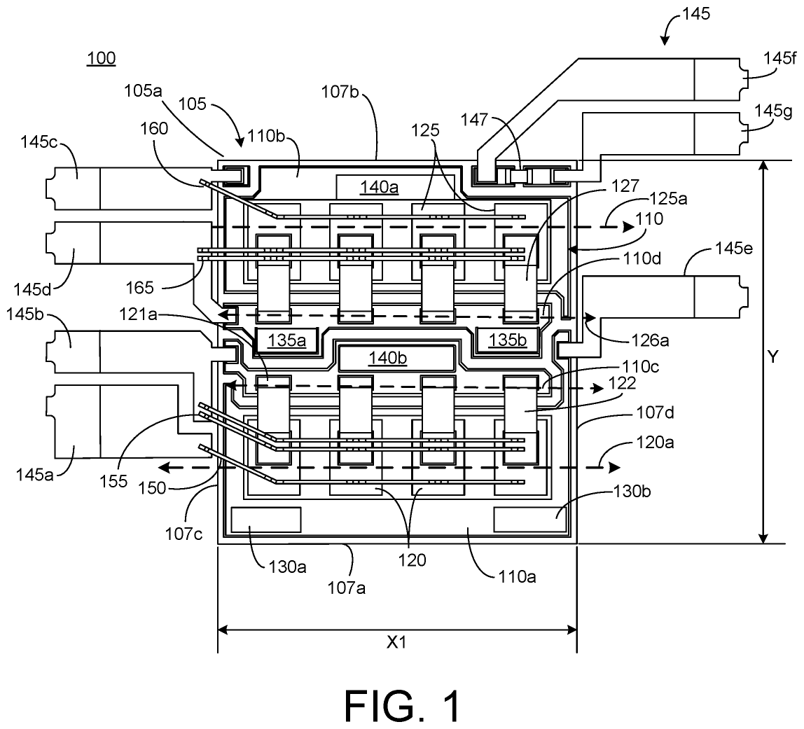

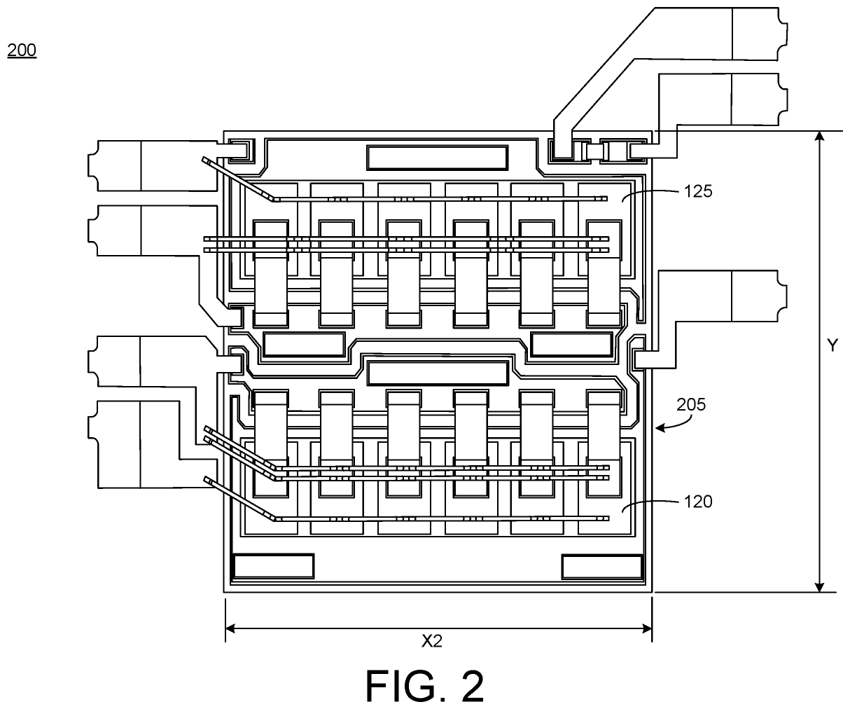

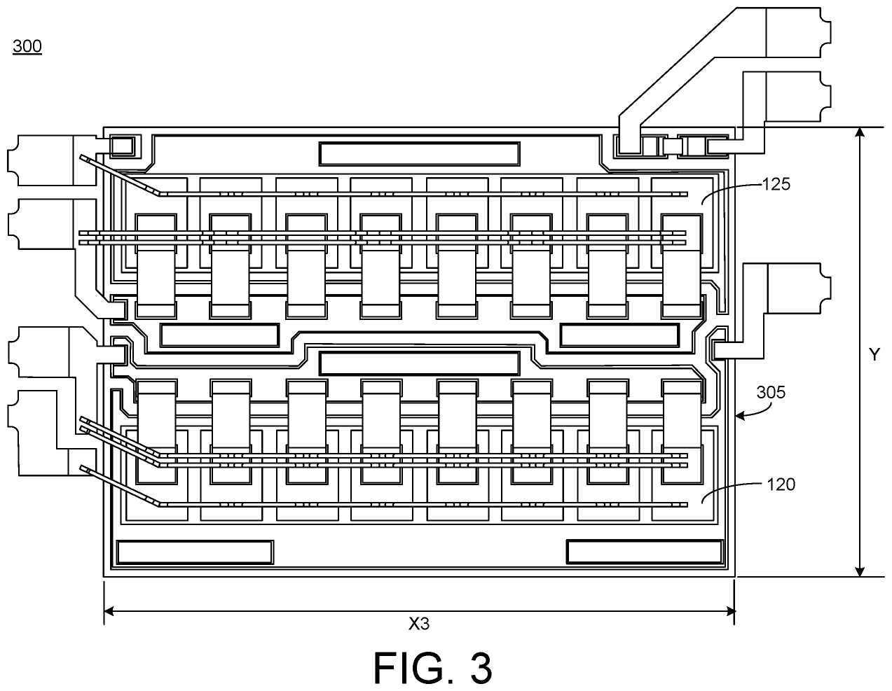

FIG. 1 is a diagram illustrating an example substrate assembly 100 of a semiconductor device module package. The substrate assembly 100 includes a DBM substrate 105, which can be a DBC substrate. As shown in FIG. 1, the DBM substrate 105 has dimensions of X1 and Y For purposes of illustration and discussion, these dimensions are described as being, respectively, along an x-axis and along a y-axis. As discussed further below with respect to at least FIGS. 2 and 3, the DBM substrate 105 can be scaled along the x-axis (e.g., by changing the dimension X1), without changing the dimension in the y-axis (e.g., the dimension Y) to accommodate fewer, or more semiconductor die. As shown in FIG. 1, the DBM substrate 105 includes a ceramic layer 105a with a patterned metal layer 110 disposed on a primary surface of the ceramic layer 105a. The patterned metal layer 110, in this example, includes a metal layer portion 110a, a metal layer portion 110b, a metal layer portion 110c, and a metal layer portion 110d. The patterned metal layer 110 also includes additional portions that are not specifically referenced in FIG. 1.

The substrate assembly 100 includes high-side transistors 120, for example, four high-side transistors 120. The high-side transistors 120 are disposed on the metal layer portion 110a in a single row. That is, the high-side transistors 120 are linearly arranged along an axis 120a. In this example, the high-side transistors 120 can be implemented using respective semiconductor die including the power transistors, such as power metal-oxide-semiconductor field-effect transistors (MOSFETs). In this example, respective drain terminals of the high-side transistors 120 are coupled with the metal layer portion 110a. Also in this example, source terminals of the high-side transistors 120 are respectively coupled with the metal layer portion 110c using conductive clips 122. As shown in FIG. 1, the metal layer portion 110c is arranged along an axis 121a that is disposed between the metal layer portion 110a and the metal layer portion 110b, and parallel to the axis 120a.

The substrate assembly 100 also includes low-side transistors 125, for example, four low-side transistors 125. The low-side transistors 125 are disposed on the metal layer portion 110b in a single row. That is, the low-side transistors 125 are linearly arranged along an axis 125a, where the axis 125a is parallel to the axis 120a. In this example, as with the high-side transistors 120, the low-side transistors 125 can be implemented using respective semiconductor die including power transistors, such as power MOSFETs. In this example, respective drain terminals of the high-side transistors 120 are coupled with the metal layer portion 110a. Also in this example, source terminals of the low-side transistors 125 are respectively coupled with the metal layer portion 110d using conductive clips 127. As shown in FIG. 1, the metal layer portion 110d is arranged along an axis 126a that is disposed between the metal layer portion 110c and the metal layer portion 110b, and parallel to the axis 120a, parallel to the axis 121a, and parallel to the axis 125a.

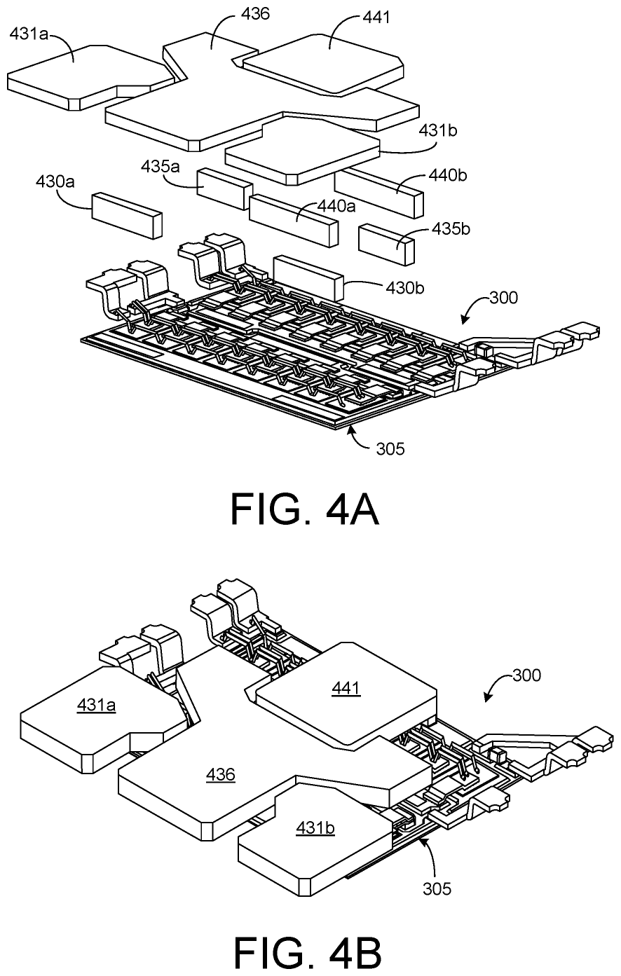

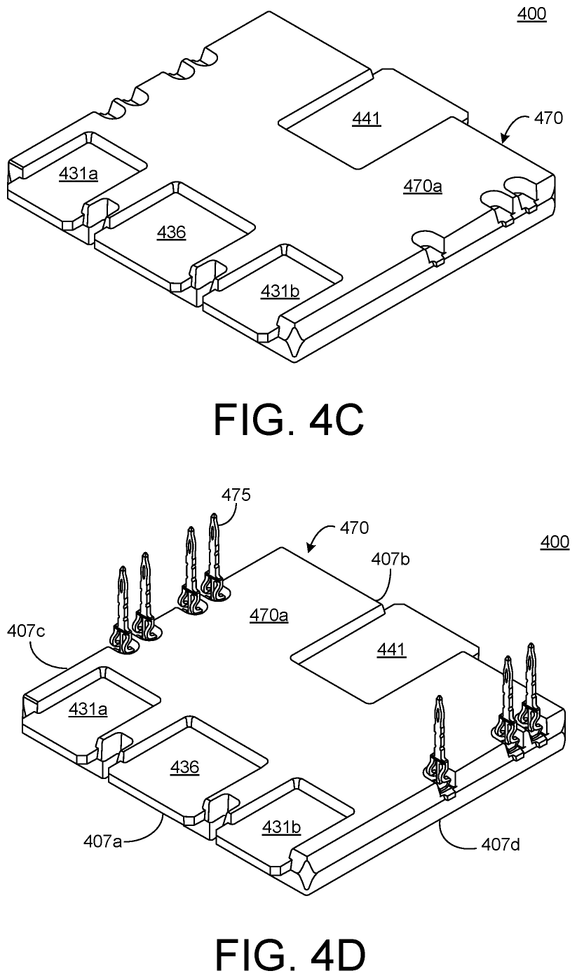

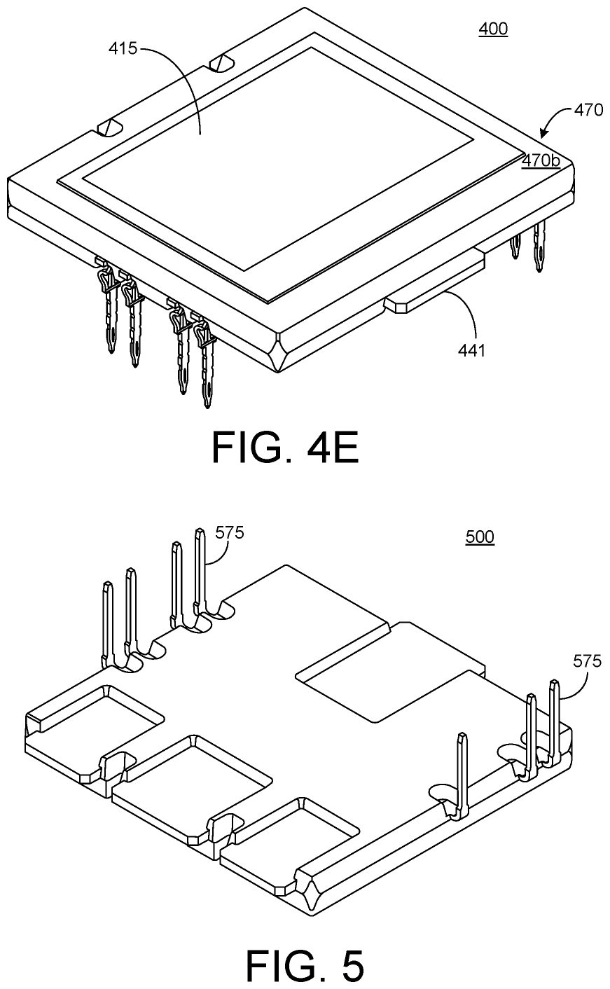

As shown in FIG. 1, the substrate assembly 100 includes a conductive post 130a, a conductive post 130b, a conductive post 135a, a conductive post 135b, a conductive post 140a, and a conductive post 140b. In this example, a first positive power supply terminal can be coupled with the metal layer portion 110a via the conductive post 130a, while a second positive power supply terminal can be coupled with the metal layer portion 110a via the conductive post 130b. That is, the positive power supply terminals can be coupled with respective drain terminals of the high-side transistors 120 vias the conductive post 130a, the conductive post 130b, and/or the metal layer portion 110a. Also in this example, a negative power supply terminal can be coupled with the metal layer portion 110d via the conductive post 135a and the conductive post 135b. That is, the negative power supply terminal can be coupled with respective source terminals of the low-side transistors 125 via the conductive post 135a, the conductive post 135b, the metal layer portion 110a, and the conductive clips 127. As shown in, for example, FIGS. 4A-4D, such power supply terminals can be arranged, or located along an edge 107a of the DBM substrate 105, where the edge 107a is parallel with the axis 120a, the axis 121a, the axis 125a, and the axis 126a.

Further in this example, a switch node terminal, or output terminal of the half-bridge circuit can be coupled with the metal layer portion 110b via the conductive post 140a, and coupled with the metal layer portion 110d via the conductive post 140b. That is, the output terminal can be coupled with respective drain terminals of the low-side transistors 125 via the conductive post 140a, and the metal layer portion 110b. Further, the output terminal can be coupled with respective source terminals of the high-side transistors 120 via the conductive post 140b, the metal layer portion 110c, and the conductive clips 122. As shown in, for example, FIGS. 4A-4D, such power supply terminals can be arranged, or located along an edge 107b of the DBM substrate 105, where the edge 107b is opposite from, and parallel with the edge 107a.

The substrate assembly 100 further includes a leadframe 145, which can include a plurality a plurality of signal leads. For instance, in the example of FIG. 1, the leadframe 145 includes a signal lead 145a, a signal lead 145b, a signal lead 145c, a signal lead 145d, a signal lead 145e, a signal lead 145f, and a signal lead 145g. The particular arrangement of the signal leads of a substrate assembly will depend on the particular implementations. Examples of signal lead and/or signal pin implementations, are shown in, at least, FIGS. 4D and 5, and discussed further below.

In the example substrate assembly 100 of FIG. 1, the signal lead 145a is a high-side transistor gate signal lead. For instance, the signal lead 145a is coupled, via a bond wire 150, with respective gate terminals of the high-side transistors 120. That is, a single bond wire (bond wire 150) couples the signal lead 145a with respective gate terminals of each of the high-side transistors 120. The signal lead 145b of the substrate assembly 100 is a high-side transistor source sense signal lead. As shown in FIG. 1, the signal lead 145b is coupled, via bond wires 155, with respective sources terminals of the high-side transistors 120 via the conductive clips 122. That is, in this example, each of the bond wires 155 couples the signal lead 145b with each of the conductive clips 122 and their corresponding high-side transistor source terminals. In this example, the signal lead 145b is also directly coupled with the metal layer portion 110c.

Further in the example substrate assembly 100 of FIG. 1, the signal lead 145c is a low-side transistor gate signal lead. For instance, the signal lead 145c is coupled, via a bond wire 160, with respective gate terminals of the low-side transistors 125. That is, a single bond wire (bond wire 160) couples the signal lead 145c with a respective gate terminals of each of the low-side transistors 125. The signal lead 145d of the substrate assembly 100 is a low-side transistor source sense signal lead. As shown in FIG. 1, the signal lead 145d is coupled, via bond wires 165, with respective sources terminals of the low-side transistors 125 via the conductive clips 127. That is, in this example, each of the bond wires 165 couples the signal lead 145d with each of the conductive clips 127 and their corresponding low-side transistor source terminals. Further in this example, the signal lead 145d is also directly coupled with the metal layer portion 110d, such as via direct lead attachment using soldering, sintering, or other lead attachment process.

As shown in FIG. 1, in the substrate assembly 100, the signal lead 145e is coupled with metal layer portion 110a. Accordingly, in this example, the signal lead 145e is a positive power supply sense signal lead, as it is coupled with respective drain terminals of the high-side transistors 120 via the metal layer portion 110a.

The substrate assembly 100 further includes a thermistor 147, which can be used for temperature sensing during operation of the half-bridge circuit of the substrate assembly 100. For instance, the signal lead 145f and the signal lead 145g are coupled with the thermistor 147. Accordingly, the signal lead 145f and the signal lead 145g can be referred to as thermal sense signal leads.

As is shown in, for example, FIGS. 4D and 5, signal pins associated with the signal leads 145a-145g can be arranged along edges of a package respectively corresponding with an edge 107c and an edge 107d of the DBM substrate 105. In this example, the edge 107c and the edge 107d are opposite and parallel to one another, and orthogonal to the edge 107a and the edge 107b. For instance, a first plurality of signal pins or signal leads can be arranged along an edge of a package corresponding with the edge 107c, while a second plurality of signal pins can be arranged along an edge of a package corresponding with the edge 107d.

FIG. 2 is a diagram illustrating an example substrate assembly 200 of another semiconductor device module package. The substrate assembly 200 of FIG. 2 includes similar aspects as the substrate assembly 100. Accordingly for purposed of brevity, details of those aspects are not described again with respect to FIG. 2.

Comparing the substrate assembly 200 with the substrate assembly 100, the substrate assembly 200, instead of having four high-side transistors 120, and four low-side transistors 125, the substrate assembly 200 includes six high-side transistors 120 and six low-side transistors 125. Accordingly, in this example, a DBM substrate 205 of the substrate assembly 200 is scaled in the x-axis from the DBM substrate 105 of the substrate assembly 100. That is, in the substrate assembly 200 a dimension X2 of the DBM substrate 205, for same size high-side transistors 120 and low-side transistors 125, is greater than the dimension X1 of the substrate assembly 100, so as to provide additional substrate surface area for the two additional high-side transistors 120 and the two additional low-side transistors 125. As noted above, in this example the dimension of the DBM substrate 205 can be equal to the dimension Y of the DBM substrate 105.

FIG. 3 is a diagram illustrating an example substrate assembly 300 of another semiconductor device module package. The substrate assembly 300 of FIG. 3, as with the substrate assembly 200, includes similar aspects as the substrate assembly 100. Accordingly for purposed of brevity, details of those aspects are not described again with respect to FIG. 3.

Comparing the substrate assembly 300 with the substrate assembly 100 and the substrate assembly 200, the substrate assembly 300, instead of having four or six high-side transistors 120, and four or six low-side transistors 125, the substrate assembly 300 includes eight high-side transistors 120 and eight low-side transistors 125. Accordingly, in this example, a DBM substrate 305 of the substrate assembly 200 is scaled in the x-axis from the DBM substrate 105 of the substrate assembly 100 and the DBM substrate 205 of the substrate assembly 200. That is, in the substrate assembly 300 a dimension X3 of the DBM substrate 305, for same size high-side transistors 120 and low-side transistors 125, is greater than the dimension X1 of the substrate assembly 100 and greater than the dimension X2 of the substrate assembly 200, so as to provide additional substrate surface area for the additional high-side transistors 120 and the additional low-side transistors 125. As noted above, in this example the dimension of the DBM substrate 205 can be equal to the dimension Y of the DBM substrate 105 and the dimension Y of the DBM substrate 205.

As illustrated by the substrate assembly 100, the substrate assembly 200 and the substrate assembly 300, associated substrates can be readily designed and produced by scaling along a single axis, or in a single direction, In some implementations, substates assemblies have fewer than four high-side transistors 120 and low-side transistors 125 can be produces, and a corresponding substrate that is similar to the DBM substrate 105, the DBM substrate 205 and the DBM substrate 305 can be produced by scaling in the x-axis, where a resultant dimension in the x-axis would be less than the dimension X1 of the substrate assembly 100.

FIGS. 4A-4e are diagrams illustrating various views of an example semiconductor device module package 400 and components thereof. The example of FIGS. 4A-4E includes the substrate assembly 300 of FIG. 3 for purpose of illustration. In some implementations, other substrate assemblies could be used, such as the substrate assembly 100, or the substrate assembly 200.

FIG. 4A is an exploded view of portions of the semiconductor device module package 400 including the substrate assembly 300 along with associated power terminals and conductive posts, where the conductive posts are referenced with 400 series reference numbers corresponding to the 100 series reference number of the conductive posts of the substrate assembly 100 of FIG. 1. For instance, in the example of FIG. 4A, a positive power supply terminal 431a (DC+ terminal) can be coupled to the DBM substrate 305 of the substrate assembly 300 via a conductive post 430a, and a positive power supply terminal 431b (DC+ terminal) can be coupled to the DBM substrate 305 of the substrate assembly 300 via a conductive post 430b. A negative power supply terminal 436 (DC− terminal) can be coupled with the DBM substrate 305 via a conductive post 435a and a conductive post 435b. Also, a switch node terminal 441 (A/C output terminal) can be coupled to the DBM substrate 305 via a conductive post 440a and a conductive post 440b. FIG. 4B is a diagram illustrating an unexploded view of the example of FIG. 4A. That is, in the view of FIG. 4B, the power terminals and the switch node terminals of FIG. 4A are shown as being coupled with the DBM substrate 305 of the substrate assembly 300 via their respective conductive posts.

FIG. 4C illustrates the assembly of FIG. 4B after performance of a molding operation, such as a transfer molding operation, to encapsulate portions of the assembly in a molding compound 470. As shown in FIG. 4C, the respective surfaces of the positive power supply terminal 431a, the positive power supply terminal 431b, the negative power supply terminal 436, and the switch node terminal 441 are exposed through a primary surface 470a of the molding compound 470. That is, the positive power supply terminal 431a, the positive power supply terminal 431b, the negative power supply terminal 436, and the switch node terminal 441 are partially encapsulated in the molding compound 470. As also shown in FIG. 4C, portions of the leadframe of the substrate assembly 300 are also exposed through the primary surface 470a of the molding compound 470.

FIG. 4D illustrates the semiconductor device module package 400 of the FIG. 4C after attachment of a first plurality of signal pins 475 along an edge 407c of the semiconductor device module package 400, and attachment of a second plurality of signal pins 475 along an edge 407d of the semiconductor device module package 400. As further illustrated in FIG. 4D, the positive power supply terminal 431a, the positive power supply terminal 431b and the negative power supply terminal 436 are arranged along, or located on an edge 407a of the semiconductor device module package 400. The switch node terminal 441 in FIG. 4D is arranged along, or located on an edge 407b of the semiconductor device module package 400. The signal pins 475, in this example, are signal pins that are configured for press-fit coupling, or frictional coupling in a corresponding circuit board. In some implementations, the signal pins 475 can be soldered and/or sintered to the portions of the corresponding leadframe exposed through the molding compound 470.

With further reference to the example of FIG. 1, in some implementations, the edge 407a of the semiconductor device module package 400 can correspond with the edge 107a of the DBM substrate 105. The edge 407b of the semiconductor device module package 400 can correspond with the edge 107b of the DBM substrate 105. The edge 407c of the semiconductor device module package 400 can correspond with the edge 107c of the DBM substrate 105. The edge 407d of the semiconductor device module package 400 can correspond with the edge 107d of the DBM substrate 105. That is, the edge 407b is opposite from and parallel to the edge 407a of the semiconductor device module package 400. The edge 407d is opposite from and parallel to the edge 407d of the semiconductor device module package 400. The edge 407c and the edge 407d are orthogonal to the edge 407a and the edge 407b.

FIG. 4E is a diagram illustrating the semiconductor device module package 400 inverted and rotated from the view of the semiconductor device module package 400 in FIG. 4D. As shown in FIG. 4E, a metal layer 415 of a corresponding DBM substrate, such as the DBM substrate 305 is exposed thorough a primary surface 470b of the molding compound 470, where the primary surface 470b is opposite the primary surface 470a of the molding compound 470. In this example, the metal layer 415 can be disposed on, included on, and/or define a primary surface of the DBM substrate 305 that is opposite a primary surface of the DBM substrate 305 on which a patterned metal layer and semiconductor switches are disposed.

FIG. 5 is a diagram illustrating another example semiconductor device module package 500. The semiconductor device module package 500 differ from the semiconductor device module package 400 in that signal pins 575 of the semiconductor device module package 500 are formed, such as using a metal working process, from signal leads of a leadframe of the semiconductor device module package 500. That is, in the semiconductor device module package 500, the signal leads of the leadframe and respective signal pins can be monolithic, rather than the signal pins being separate elements that are coupled with (sintered or solder to) exposed portions of the signal leads of a corresponding leadframe.

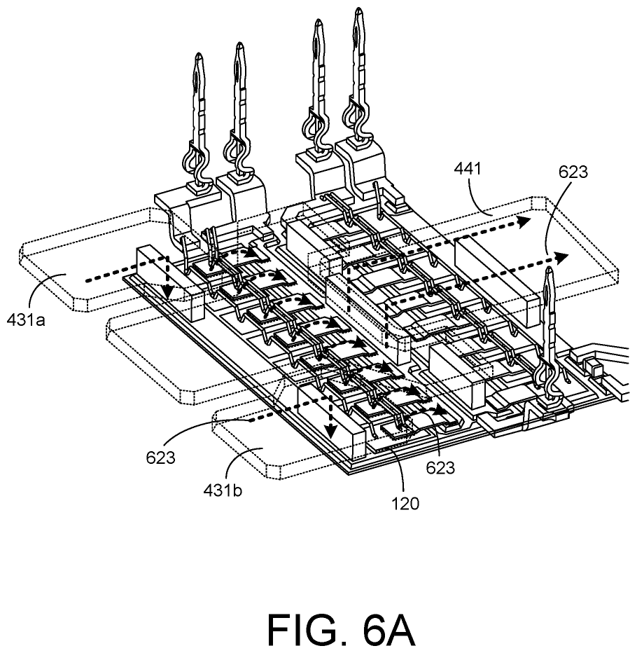

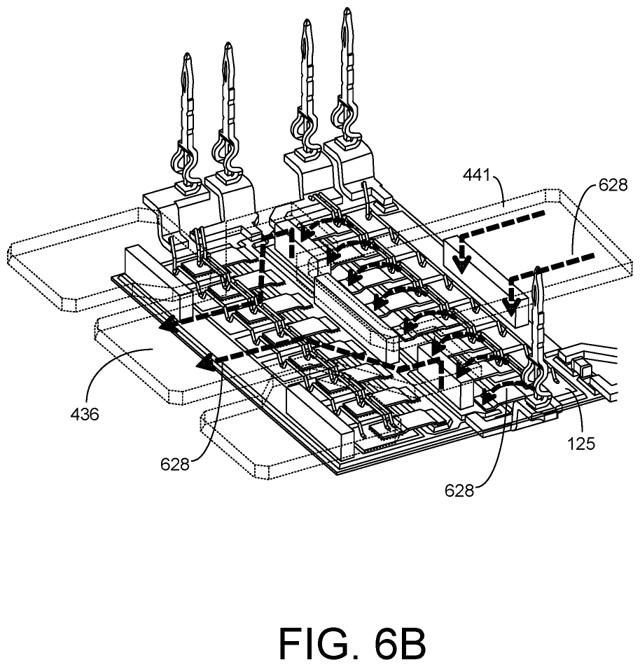

FIGS. 6A and 6B are diagrams illustrating current flow in the semiconductor device module package of FIGS. 4A-4E. FIG. 6A illustrates current flow 623, illustrated by dashed-arrows, through the high-side transistors 120. As shown in FIG. 6A, the current flow 623 is from the positive power supply terminal 431a and the positive power supply terminal 431b to the switch node terminal 441. That is, the current flow 623 is from the positive power supply terminal 431a and the positive power supply terminal 431b, through the high-side transistors 120, as well as corresponding conductive posts, conductive clips and metal layer portions, to the 441a// and the 441b//. The current flow 623 shown in FIG. 6A can be referred to as high-side current.

In comparison to FIG. 6A, FIG. 6B illustrates current flow 628, illustrated by dashed-arrows, through the low-side transistors 125. As shown in FIG. 6B, the current flow 628 is from the switch node terminal 441 to the negative power supply terminal 436. That is, the current flow 628 is from the switch node terminal 441, through the low-side transistors 125, as well as corresponding conductive posts, conductive clips and metal layer portions, to the negative power supply terminal 436. The current flow 628 shown in FIG. 6B can be referred to as low-side current.

In the example of FIGS. 6A and 6B, the current flow 623 and the current flow 628 are counter currents, or currents that are parallel, but in opposite directions. This arrangement, and the resulting countercurrents can reduce stray inductance of the power modules described herein, as such countercurrent flows will provide mutual cancellation of respective magnetic fields associated with the current flow 623 (high-side current) and the current flow 628 (low-side current), where such magnetic fields, uncancelled, increase stray inductance.

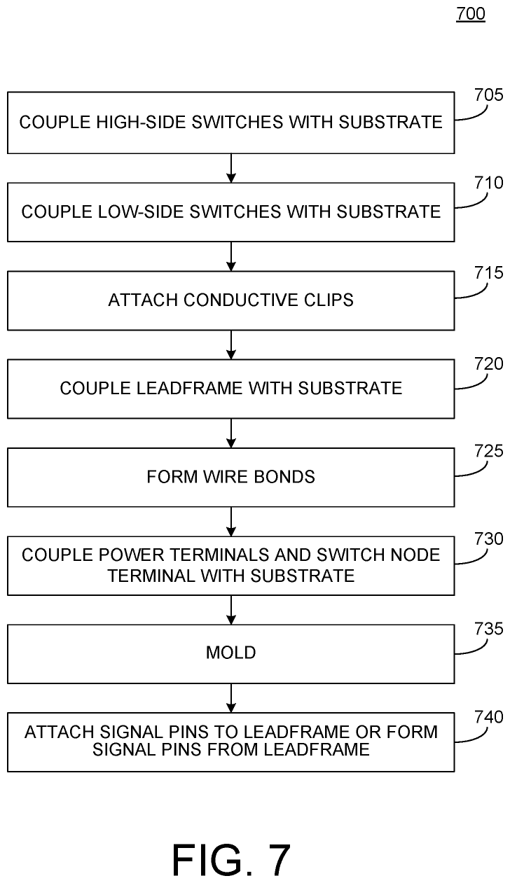

FIG. 7 is a flowchart illustrating an example method 700 for producing a power module package, such as the packages described herein. The method 700, at block 705, includes coupling a plurality of high-side semiconductor switches, such as the high-side transistors 120, with a first portion of a patterned metal layer of a substrate, such as the metal layer portion 110a of the DBM substrate 105. In this example, the plurality of high-side semiconductor switches can be linearly arranged on the substrate along a first axis, such as the axis 120a.

At block 710, the method 700 includes coupling a plurality of low-side semiconductor switches, such as the low-side transistors 125, with a second portion of the patterned metal layer, such as the metal layer portion 110b. In this example, the plurality of low-side semiconductor switches can be linearly arranged on the substrate along a second axis, such as the axis 125a, which is parallel to the first axis. In some implementations, the operations of block 705 and 710 can be performed together using, for instance, a soldering operation and/or a sintering operation.

At block 715, the method 700 includes coupling or attaching conductive clips to the semiconductor switches and the substrate, such as the conductive clips 122 and the conductive clips 127. For example, in some implementations, such as the substrate assembly 100 of FIG. 1, the conductive clips can connect source terminals of high-side transistors 120 with the metal layer portion 110c, and connect source terminals of the low-side transistors 125 with the metal layer portion 110d. In some implementations, the operations of block 715 can include a soldering operation and/or a sintering operation.

At block 720, the method 700 includes coupling, or attaching a leadframe, such as at least one signal lead of a leadframe, with the substrate. The leadframe can be a single body leadframe (e.g., signal leads within a support frame), which is subsequently trimmed to separate the individual signal leads. For instance, referring to the substrate assembly 100 of FIG. 1, the operations at block 720 can include coupling signal leads 145b-145g of the leadframe 145 with the DBM substrate 105. At block 725, the method includes forming wire bonds between the signal leads of the leadframe, the semiconductor switches and/or the conductive clips, such as wire bonds of the bond wires 150, 155, 160 and 165 of the substrate assembly 100.

At block 730, the method 700 includes coupling power terminals, such as the positive power supply terminal 431a, the positive power supply terminal 431b, and the negative power supply terminal 436, with the substrate via conductive posts, such as the conductive posts 430a, 430b, 435a and 435b. In this example, the power terminals are arranged along, or located on a first edge of the package, such as the edge 407a in FIG. 4D. The method 700, at block 730, also includes coupling a switch node terminal, such as the switch node terminal 441, with the substrate via conductive posts, such as the conductive posts 440a and 440b. The switch node terminal, in this example, is arranged, or located along a second edge of the package, such as the edge 407b in FIG. 4D. The second edge (the edge 407b), in this example, is opposite to, and parallel with the first edge (the edge 407a). The operations at block 730 can include soldering, sintering or welding the conductive posts and associated terminals.

At block 735, the method 700 includes performing a molding process, such as a transfer molding process, to encapsulate portions of the semiconductor device package in a molding compound, as the molding compound 470 of FIGS. 4C, 4D, and 4E. In some implementations, such as those described herein, the power terminals and output terminal of block 730 can be exposed through a primary surface of the molding compound, such as the positive power supply terminal 431a, the positive power supply terminal 431b, the negative power supply terminal 436, and the switch node terminal 441 are exposed through a primary surface 470a of the molding compound 470. Further in this example, portions of the leadframe can also be exposed through the primary surface 470a of the molding compound 470, such as in the example shown in FIG. 4C.

At block 740, the method 700 includes coupling, or attaching signal pins, such as the signal pins 475, to the exposed portions of the leadframe of block 720, for example, along the edge 407c and the edge 407d of the semiconductor device module package 400. For instance, the signal pins can be soldered or sintered to respective exposed portions of the leadframe, such as in the example illustrated in FIGS. 4C and 4D. In some implementations, rather than being separate elements that are coupled with a leadframe, the signal pins can be formed from the signal leads of the leadframe, such the signal pins 575 of FIG. 5. In some implementations, the method 700 can include additional operations, such as flux cleaning operations, deflash operations, and/or trim and form operations. In some implementations, one or more operations of the method 700 can be omitted, or can be replaced with alternative, or different operations.

In a general aspect, a power module package includes a substrate including a ceramic layer having a first primary surface and a second primary surface opposite the first primary surface, and a patterned metal layer disposed on the first primary surface. The power module package further includes a first plurality of semiconductor die disposed on a first portion of the patterned metal layer. The first plurality of semiconductor die are linearly arranged along a first axis. The power module package also includes a second plurality of semiconductor die disposed on a second portion of the patterned metal layer. The second plurality of semiconductor die are linearly arranged along a second axis parallel to the first axis. The power module package also includes a plurality of power terminals arranged on a first edge of the power module package, where the first edge is parallel to the first axis and the second axis. The power module package also includes a switch node terminal arranged on a second edge of the power module package, where the second edge being opposite and parallel to the first edge. The power module package further includes a first plurality of signal pins located on a third edge of the power module package that is orthogonal to the first edge and the second edge, and a second plurality of signal pins located on a fourth edge of the power module package, the fourth edge being opposite and parallel to the third edge.

Implementations can include one or more of the following features or aspects, alone or in combination. For example, the substrate can include a metal layer disposed on the second primary surface. The power module package can include a molding compound encapsulating the first plurality of semiconductor die and the second plurality of semiconductor die, and partially encapsulating the substrate. The metal layer can be exposed through the molding compound.

The plurality of power terminals and the switch node terminal can be exposed through a first primary surface of the molding compound.

The first primary surface of the molding compound can be located on a side of the substrate corresponding with the first primary surface of the substrate.

The metal layer can be exposed through the molding compound on a second primary surface of the molding compound opposite the first primary surface of the molding compound.

The power module package can include a leadframe. The first plurality of signal pins and the second plurality of signal pins can be included in the leadframe. The first plurality of signal pins and the second plurality of signal pins can be coupled with the leadframe.

The power module package can include a first plurality of conductive clips respectively coupling the first plurality of semiconductor die with a third portion of the patterned metal layer disposed between the first portion of the patterned metal layer and the second portion of the patterned metal layer. The third portion of the patterned metal layer can be arranged along a third axis that is parallel with the first axis and the second axis. The power module package can include a second plurality of conductive clips respectively coupling the second plurality of semiconductor die with a fourth portion of the patterned metal layer disposed between the second portion of the patterned metal layer and the third portion of the patterned metal layer. The fourth portion of the patterned metal layer can be arranged along a fourth axis that is parallel with the first axis, the second axis, and the third axis.

In another general aspect, a power module package include a substrate including a patterned metal layer disposed thereon. The power module package also includes a first plurality of semiconductor die disposed on a first portion of the patterned metal layer. The first plurality of semiconductor die include a first plurality of power transistors that are linearly arranged along a first axis. The power module package further includes a second plurality of semiconductor die disposed on a second portion of the patterned metal layer. The second plurality of semiconductor die include a second plurality of power transistors that are linearly arranged along a second axis parallel to the first axis. The power module package also includes a first plurality of conductive clips respectively coupling the first plurality of power transistors with a third portion of the patterned metal layer disposed between the first portion of the patterned metal layer and the second portion of the patterned metal layer. The third portion of the patterned metal layer is arranged along a third axis that is parallel with the first axis and the second axis. The power module package also include a second plurality of conductive clips respectively coupling the second plurality of power transistors with a fourth portion of the patterned metal layer disposed between the second portion of the patterned metal layer and the third portion of the patterned metal layer. The fourth portion of the patterned metal layer is arranged along a fourth axis that is parallel with the first axis, the second axis, and the third axis.

Implementations can include one or more of the following features or aspects, alone or in combination. For example, the power module package can include a plurality of power terminals arranged on a first edge of the power module package. The first edge can be parallel to the first axis and the second axis. The power module package can include a switch node terminal arranged on a second edge of the power module package. The second edge can be opposite and parallel to the first edge.

The power module package can include a first plurality of signal pins located on a third edge of the power module package that is orthogonal to the first edge and the second edge. The power module package can include a second plurality of signal pins located on a fourth edge of the power module package. The fourth edge can be opposite and parallel to the third edge.

The first plurality of power transistors can be respective high-side transistors of a half-bridge circuit including first respective power metal-oxide-semiconductor field-effect transistors (MOSFETs). The second plurality of power transistors can be respective low-side transistors of the half-bridge circuit including second respective power MOSFETs.

Respective drain terminals of the first respective power MOSFETs can be coupled with the first portion of the patterned metal layer. Respective source terminals of the first respective power MOSFETs can be coupled with the third portion of the patterned metal layer via the first plurality of conductive clips. Respective drain terminals of the second respective power MOSFETs can be coupled with the second portion of the patterned metal layer. Respective source terminals of the second respective power MOSFETs can be coupled with the fourth portion of the patterned metal layer vias the second plurality of conductive clips.

The power module package can include a high-side source sense signal lead. A first bond wire can couple the high-side source sense signal lead with the first plurality of conductive clips. The power module package can include a high-side gate terminal signal lead. A second bond wire can couple the high-side gate terminal signal lead with respective gate terminals of the first respective power MOSFETs.

The power module package can include a low-side source sense signal lead. A first bond wire can couple the low-side source sense signal lead with the second plurality of conductive clips. The power module package can include a low-side gate terminal signal lead. A second bond wire can couple the low-side gate terminal signal lead with respective gate terminals of the second respective power MOSFETs.

The power module package can include a positive power supply terminal coupled with the first portion of the patterned metal layer. The power module package can include a negative power supply terminal coupled with the fourth portion of the patterned metal layer. The power module package can include a switch node terminal coupled with the second portion of the patterned metal layer and the third portion of the patterned metal layer.

The positive power supply terminal can be coupled with the first portion of the patterned metal layer via a first conductive post. The negative power supply terminal can be coupled with the fourth portion of the patterned metal layer via a second conductive post. The switch node terminal can be coupled with the second portion of the patterned metal layer via a third conductive post, coupled with the third portion of the patterned metal layer via a fourth conductive post.

The negative power supply terminal can be coupled with the fourth portion of the patterned metal layer via a fifth conductive post.

The positive power supply terminal can be a first positive power supply terminal. The power module package can include a second positive power terminal that is coupled with the first portion of the patterned metal layer via a fifth conductive post.

In another general aspect, a method for producing a power module package includes coupling a first plurality of semiconductor die with a first portion of a patterned metal layer of a substrate and a second portion of the patterned metal layer. The first plurality of semiconductor die are linearly arranged on the substrate along a first axis. The method also includes coupling a second plurality of semiconductor die with a third portion of the patterned metal layer and a fourth portion of the patterned metal layer. The second plurality of semiconductor die are linearly arranged on the substrate along a second axis parallel to the first axis. The method further includes coupling a plurality of power terminals with the substrate. The plurality of power terminals are arranged on a first edge of the power module package. The first edge is parallel to the first axis and the second axis. The method also includes coupling a switch node terminal with the substrate. The switch node terminal is arranged on a second edge of the power module package. The second edge is opposite and parallel to the first edge. The method further includes coupling a leadframe with the substrate, and forming respective wire bonds coupling the leadframe with the first plurality of semiconductor die and the second plurality of semiconductor die. The method also includes coupling a first plurality of signal pins with respective portions of the leadframe. The first plurality of signal pins is located on a third edge of the power module package that is orthogonal to the first edge and the second edge. The method further includes coupling a second plurality of signal pins with respective portions of the leadframe. The second plurality of signal pins is located on a fourth edge of the power module package. The fourth edge is opposite and parallel to the third edge.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A power module package comprising:
a substrate including:
a ceramic layer having a first primary surface and a second primary surface opposite the first primary surface; and
a patterned metal layer disposed on the first primary surface;
a first plurality of semiconductor die disposed on a first portion of the patterned metal layer, the first plurality of semiconductor die being linearly arranged along a first axis;
a second plurality of semiconductor die disposed on a second portion of the patterned metal layer, the second plurality of semiconductor die being linearly arranged along a second axis parallel to the first axis;
a plurality of power terminals arranged on a first edge of the power module package, the first edge being parallel to the first axis and the second axis;
a switch node terminal arranged on a second edge of the power module package, the second edge being opposite and parallel to the first edge;
a first plurality of signal pins located on a third edge of the power module package that is orthogonal to the first edge and the second edge; and
a second plurality of signal pins located on a fourth edge of the power module package, the fourth edge being opposite and parallel to the third edge.

2. The power module package of claim 1, wherein:
the substrate further includes a metal layer disposed on the second primary surface; and
the power module package further comprises a molding compound encapsulating the first plurality of semiconductor die and the second plurality of semiconductor die, and partially encapsulating the substrate, the metal layer being exposed through the molding compound.

3. The power module package of claim 2, wherein the plurality of power terminals and the switch node terminal are exposed through a first primary surface of the molding compound.

4. The power module package of claim 3, wherein the first primary surface of the molding compound is located on a side of the substrate corresponding with the first primary surface of the substrate.

5. The power module package of claim 3, wherein the metal layer is exposed through the molding compound on a second primary surface of the molding compound opposite the first primary surface of the molding compound.

6. The power module package of claim 1, further comprising a leadframe, the first plurality of signal pins and the second plurality of signal pins being included in the leadframe.

7. The power module package of claim 1, further comprising a leadframe, the first plurality of signal pins and the second plurality of signal pins being coupled with the leadframe.

8. The power module package of claim 1, further comprising:
a first plurality of conductive clips respectively coupling the first plurality of semiconductor die with a third portion of the patterned metal layer disposed between the first portion of the patterned metal layer and the second portion of the patterned metal layer, the third portion of the patterned metal layer being arranged along a third axis that is parallel with the first axis and the second axis; and
a second plurality of conductive clips respectively coupling the second plurality of semiconductor die with a fourth portion of the patterned metal layer disposed between the second portion of the patterned metal layer and the third portion of the patterned metal layer, the fourth portion of the patterned metal layer being arranged along a fourth axis that is parallel with the first axis, the second axis, and the third axis.

9. A power module package comprising:
a substrate including a patterned metal layer disposed thereon;
a first plurality of semiconductor die disposed on a first portion of the patterned metal layer, the first plurality of semiconductor die including a first plurality of power transistors that are linearly arranged along a first axis;
a second plurality of semiconductor die disposed on a second portion of the patterned metal layer, the second plurality of semiconductor die including a second plurality of power transistors that are linearly arranged along a second axis parallel to the first axis;
a first plurality of conductive clips respectively coupling the first plurality of power transistors with a third portion of the patterned metal layer disposed between the first portion of the patterned metal layer and the second portion of the patterned metal layer, the third portion of the patterned metal layer being arranged along a third axis that is parallel with the first axis and the second axis; and
a second plurality of conductive clips respectively coupling the second plurality of power transistors with a fourth portion of the patterned metal layer disposed between the second portion of the patterned metal layer and the third portion of the patterned metal layer, the fourth portion of the patterned metal layer being arranged along a fourth axis that is parallel with the first axis, the second axis, and the third axis.

10. The power module package of claim 9, further comprising:
a plurality of power terminals arranged on a first edge of the power module package, the first edge being parallel to the first axis and the second axis; and
a switch node terminal arranged on a second edge of the power module package, the second edge being opposite and parallel to the first edge.

11. The power module package of claim 10, further comprising:
a first plurality of signal pins located on a third edge of the power module package that is orthogonal to the first edge and the second edge; and
a second plurality of signal pins located on a fourth edge of the power module package, the fourth edge being opposite and parallel to the third edge.

12. The power module package of claim 9, wherein:
the first plurality of power transistors are respective high-side transistors of a half-bridge circuit including first respective power metal-oxide-semiconductor field-effect transistors (MOSFETs); and
the second plurality of power transistors are respective low-side transistors of the half-bridge circuit including second respective power MOSFETs.

13. The power module package of claim 12, wherein:
respective drain terminals of the first respective power MOSFETs are coupled with the first portion of the patterned metal layer;
respective source terminals of the first respective power MOSFETs are coupled with the third portion of the patterned metal layer via the first plurality of conductive clips;
respective drain terminals of the second respective power MOSFETs are coupled with the second portion of the patterned metal layer; and
respective source terminals of the second respective power MOSFETs are coupled with the fourth portion of the patterned metal layer vias the second plurality of conductive clips.

14. The power module package of claim 12, further comprising:
a high-side source sense signal lead;
a first bond wire coupling the high-side source sense signal lead with the first plurality of conductive clips;
a high-side gate terminal signal lead; and
a second bond wire coupling the high-side gate terminal signal lead with respective gate terminals of the first respective power MOSFETs.

15. The power module package of claim 12, further comprising:
a low-side source sense signal lead;
a first bond wire coupling the low-side source sense signal lead with the second plurality of conductive clips;
a low-side gate terminal signal lead; and
a second bond wire coupling the low-side gate terminal signal lead with respective gate terminals of the second respective power MOSFETs.

16. The power module package of claim 12, further comprising:
a positive power supply terminal coupled with the first portion of the patterned metal layer;
a negative power supply terminal coupled with the fourth portion of the patterned metal layer; and
a switch node terminal coupled with the second portion of the patterned metal layer and the third portion of the patterned metal layer.

17. The power module package of claim 16, wherein:
the positive power supply terminal is coupled with the first portion of the patterned metal layer via a first conductive post;
the negative power supply terminal is coupled with the fourth portion of the patterned metal layer via a second conductive post;
the switch node terminal is coupled with the second portion of the patterned metal layer via a third conductive post; and
the switch node terminal is coupled with the third portion of the patterned metal layer via a fourth conductive post.

18. The power module package of claim 17, wherein the negative power supply terminal is further coupled with the fourth portion of the patterned metal layer via a fifth conductive post.

19. The power module package of claim 17, wherein the positive power supply terminal is a first positive power supply terminal,
the power module package further comprising a second positive power terminal that is coupled with the first portion of the patterned metal layer via a fifth conductive post.

20. A method for producing a power module package, the method comprising:
coupling a first plurality of semiconductor die with a first portion of a patterned metal layer of a substrate and a second portion of the patterned metal layer, the first plurality of semiconductor die being linearly arranged on the substrate along a first axis;
coupling a second plurality of semiconductor die with a third portion of the patterned metal layer and a fourth portion of the patterned metal layer, the second plurality of semiconductor die being linearly arranged on the substrate along a second axis parallel to the first axis;
coupling a plurality of power terminals with the substrate, the plurality of power terminals being arranged on a first edge of the power module package, the first edge being parallel to the first axis and the second axis;
coupling a switch node terminal with the substrate, the switch node terminal being arranged on a second edge of the power module package, the second edge being opposite and parallel to the first edge;
coupling a leadframe with the substrate;
forming respective wire bonds coupling the leadframe with the first plurality of semiconductor die and the second plurality of semiconductor die;
coupling a first plurality of signal pins with respective portions of the leadframe, the first plurality of signal pins being located on a third edge of the power module package that is orthogonal to the first edge and the second edge; and
coupling a second plurality of signal pins with respective portions of the leadframe, the second plurality of signal pins being located on a fourth edge of the power module package, the fourth edge being opposite and parallel to the third edge.
